(19) United States
(12) Patent Application Publication
(10) Pub. No.: US 2025/0266756 A1
(43) Pub. Date: Aug. 21, 2025

(54) POWER CONVERSION DEVICE

(71) Applicants: Hitachi Astemo, Ltd., Hitachinaka-shi, (JP); HONDA MOTOR CO., LTD., Tokyo (JP)

(72) Inventors: Yoshiharu TANABE, Hitachinaka-shi (JP); Kohei NAKANO, Hitachinaka-shi (JP); Takahiro UNEME, Tokyo (JP); Ryuta WAKABAYASHI, Tokyo (JP)

(21) Appl. No.: 19/049,355

(22) Filed: Feb. 10, 2025

(30) Foreign Application Priority Data
Feb. 16, 2024 (JP) 2024-022219

(51) Int. Cl. H02M 3/00; H05K 5/02

(52) U.S. Cl. CPC H02M 3/003; H05K 5/0247

(57) ABSTRACT

A power conversion device includes: a first connector held by a support plate; a second connector held by the support plate to be adjacent to the first connector; and a bus bar connecting the first connector and the second connector to at least a capacitor unit and a DC/DC converter unit, in which the support plate includes a surrounding wall portion surrounding a partition wall portion from a side thereof, and the first connector and the second connector are provided to protrude from an outer wall surface of the surrounding wall portion and are formed such that cables are mountable thereon in a direction inclined relative to a wall surface of the partition wall portion.

### CROSS REFERENCE TO RELATED APPLICATIONS

The present invention claims priority under 35 U.S.C. § 119 to Japanese Application No. 2024-022219, filed on Feb. 16, 2024, the entire contents of which being incorporated herein by reference.

### BACKGROUND OF THE INVENTION

### Field of the Invention

The present invention relates to a power conversion device.

### Description of Related Art

For example, Japanese Patent No. 6908004 (hereinafter, referred to as Patent Document 1) discloses a power conversion device that includes a plurality of high-voltage connectors.

The power conversion device disclosed in Patent Document 1 includes an input connector and an output connector as the high-voltage connectors. The input connector is configured to be connected with a connector of a power supply wiring connected to a DC power supply. The output connector is configured to be connected with a connector of a load wiring connected to an AC load such as a rotating electric machine.

In the power conversion device disclosed in Patent Document 1, the input connector and the output connector are provided to be aligned on a side surface of a case. An external connector (for example, the above-described connector of the power supply wiring or connector of the load wiring) is inserted into these input and output connectors in a horizontal direction. In this way, when a configuration is adopted in which the external connector is inserted into the connector of the power conversion device in the horizontal direction, the connector greatly protrudes to the side of the power conversion device. In addition, the external connector connected to the power conversion device also greatly protrudes to the side of the power conversion device. As a result, it is necessary to secure a large installation space for the power conversion device.

The present invention has been made in view of the above-described circumstances, and an object of the present invention is to be able to reduce the installation space for a power conversion device.

### SUMMARY OF THE INVENTION

The present invention adopts the following configuration as means for obtaining the above object.

A power conversion device of an aspect of the present invention, includes a capacitor unit, a reactor unit, a DC/DC converter unit, and a power module forming a power conversion circuit; a support plate including a flat plate-shaped partition wall portion supporting the capacitor unit, the reactor unit, the DC/DC converter unit, and the power module; a first connector held by the support plate; a second connector held by the support plate to be adjacent to the first connector; and a bus bar connecting the first connector and the second connector to at least the capacitor unit and the DC/DC converter unit, in which the support plate includes a surrounding wall portion surrounding the partition wall portion from a side thereof, and the first connector and the second connector are provided to protrude from an outer wall surface of the surrounding wall portion and are formed such that cables are mountable thereon in a direction inclined relative to a wall surface of the partition wall portion.

In the power conversion device of the present invention, the first connector and the second connector adjacent to each other are provided to protrude from an outer wall surface of the surrounding wall portion of the support plate and are formed such that cables are mountable thereon in a direction inclined relative to a flat plate-shaped partition wall portion. Therefore, it is possible to further reduce the amount of protrusion of the first connector and the second connector from the outer wall surface than a case where the cables are mounted on the first connector and the second connector in a horizontal direction with respect to the flat plate-shaped partition wall portion. In addition, it is possible to further reduce the amount of protrusion of the cables in the horizontal direction than a case where the cables are mounted on the first connector and the second connector in the horizontal direction. Therefore, the power conversion device of the present embodiment can reduce the installation space when viewed in the normal direction of the partition wall portion.

### BRIEF DESCRIPTION OF THE DRAWINGS

FIG. 1 is a schematic configuration diagram of a vehicle on which a power conversion device according to an embodiment of the present invention is mounted.

FIG. 2 is a circuit diagram showing an electrical schematic configuration of a buck-boost converter and an inverter included in the power conversion device according to the embodiment of the present invention.

FIG. 3 is an exploded perspective view showing a structural schematic configuration of the power conversion device according to the embodiment of the present invention.

FIG. 4 is a schematic cross-sectional view including a reactor unit of the power conversion device according to the embodiment of the present invention.

FIG. 5 is a schematic view in which an upper cover of a main body case of the power conversion device according to the embodiment of the present invention is omitted.

FIG. 6 is a perspective view of an internal bus bar included in the power conversion device according to the embodiment of the present invention.

FIG. 7 is a schematic view showing a stress relaxation portion provided in an intermediate portion of the internal bus bar.

### DETAILED DESCRIPTION OF THE INVENTION

In the following, an embodiment of a power conversion device according to the present invention will be described with reference to the drawings.

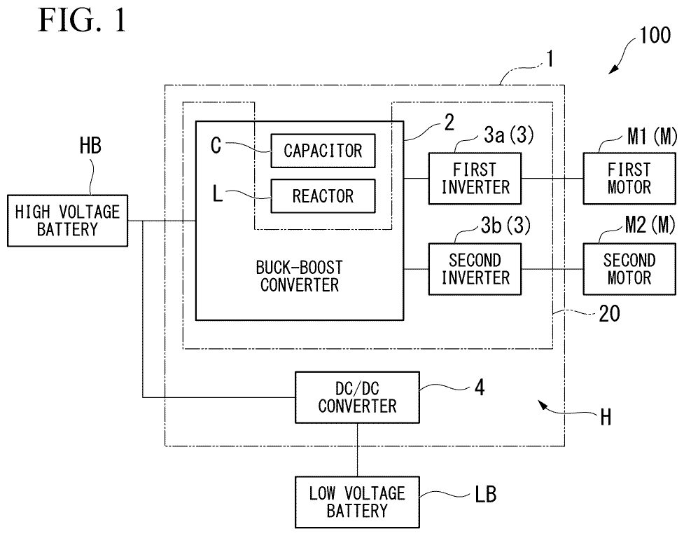

FIG. 1 is a schematic configuration diagram of a vehicle 100 on which a power conversion device 1 of the present embodiment is mounted. The vehicle 100 is, for example, an electric vehicle or a hybrid vehicle. As shown in FIG. 1, the vehicle 100 includes, for example, a high voltage battery HB, a low voltage battery LB, a motor M, and the power conversion device 1 of the present embodiment.

The high voltage battery HB is a secondary battery, such as a lithium ion battery, and outputs relatively high voltage DC power of, for example, about several hundred volts. The high voltage battery HB is a battery that outputs driving electric power to be supplied to the motor M and is a so-called driving battery. The low voltage battery LB is a secondary battery, such as a lead-acid battery, and outputs relatively low voltage DC power of, for example, about 12 V. The low voltage battery LB is a battery that outputs power for auxiliary devices to be supplied to auxiliary devices (not shown) and is a so-called auxiliary device battery.

The motor M generates rotational motive power by the driving electric power being supplied thereto from the high voltage battery HB through the power conversion device 1. The rotational motive power generated by the motor M is transmitted to drive wheels of the vehicle 100 through a transmission mechanism (not shown). In the present embodiment, the motor M includes a first motor M1 and a second motor M2. For example, the first motor M1 generates motive power to be supplied to front wheels of the vehicle 100. In addition, for example, the second motor M2 generates motive power to be supplied to rear wheels of the vehicle 100.

The power conversion device 1 of the present embodiment is a device that performs power conversion. For example, the power conversion device 1 converts DC power into AC power, converts AC power into DC power, or converts voltage. Specifically, the power conversion device 1 of the present embodiment steps up the driving electric power output from the high voltage battery HB, converts it into alternating current, and supplies the alternating current to the motor M. In addition, the power conversion device 1 of the present embodiment converts regenerative power output from the motor M into direct current, steps down it, and supplies it to the high voltage battery HB. Further, the power conversion device 1 of the present embodiment steps down the driving electric power output from the high voltage battery HB to generate power for auxiliary devices and supplies the power for auxiliary devices to the low voltage battery LB.

As shown in FIG. 1, the power conversion device 1 of the present embodiment includes a buck-boost converter 2, an inverter 3, and a DC/DC converter 4. The buck-boost converter 2, the inverter 3, and the DC/DC converter 4 constitute a power conversion circuit H that performs power conversion. The buck-boost converter 2 steps up or steps down the electric power. For example, the buck-boost converter 2 steps up the driving electric power supplied from the high voltage battery HB and outputs it to the inverter 3. In addition, the buck-boost converter 2 steps down the regenerative power supplied from the inverter 3 and outputs it to the high voltage battery HB.

The inverter 3 converts the DC power into the AC power or converts the AC power into the DC power. For example, the inverter 3 converts DC driving electric power supplied from the buck-boost converter 2 into three-phase AC power and outputs the three-phase AC power to the motor M. In addition, the inverter 3 converts AC regenerative power supplied from the motor M into DC power and outputs the DC power to the high voltage battery HB. In the present embodiment, the inverter 3 includes a first inverter 3a and a second inverter 3b. The first inverter 3a is connected to the first motor M1. Further, the second inverter 3b is connected to the second motor M2.

The DC/DC converter 4 steps down the driving electric power output from the high voltage battery HB to convert it into power for auxiliary devices. The DC/DC converter 4 converts DC driving electric power into DC power for auxiliary devices.

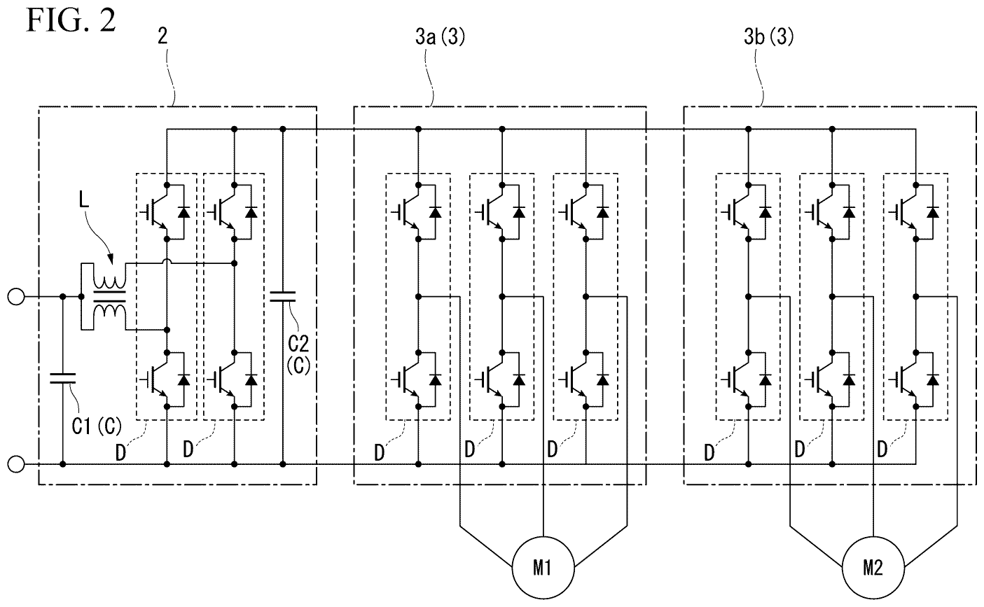

FIG. 2 is a circuit diagram showing an electrical schematic configuration of the buck-boost converter 2 and the inverter 3. As shown in FIG. 2, the power conversion device 1 of the present embodiment includes the buck-boost converter 2 and the inverter 3 that are connected to each other.

The buck-boost converter 2 includes two power devices D, two capacitors C, and a reactor L. One capacitor C (hereinafter, referred to as a first capacitor C1) of the two capacitors C stores electric power before the step-up in a case where electric power is supplied from the high voltage battery HB to the motor M. In addition, the other capacitor C (hereinafter, referred to as a second capacitor C2) of the two capacitors C stores electric power after the step-up in a case where electric power is supplied from the high voltage battery HB to the motor M. Each of the first capacitor C1 and the second capacitor C2 is not limited to being formed of a single element. The first capacitor C1 may be formed of a plurality of elements, or the second capacitor C2 may be formed of a plurality of elements.

In addition, each inverter 3 includes three power devices D. Each power device D has a power transistor. These power transistors have semiconductor elements and are mounted on an insulated circuit board. In the present embodiment, one power device D includes two power transistors. However, a power device having a single power transistor may be provided. In this case, four power devices are provided in the buck-boost converter 2, and six power devices are provided in the inverter 3. For example, each power transistor includes a plurality of semiconductor elements formed of, for example, silicon carbide (SIC). The power transistor may include a semiconductor element formed of other materials such as silicon (Si) or gallium nitride (GaN).

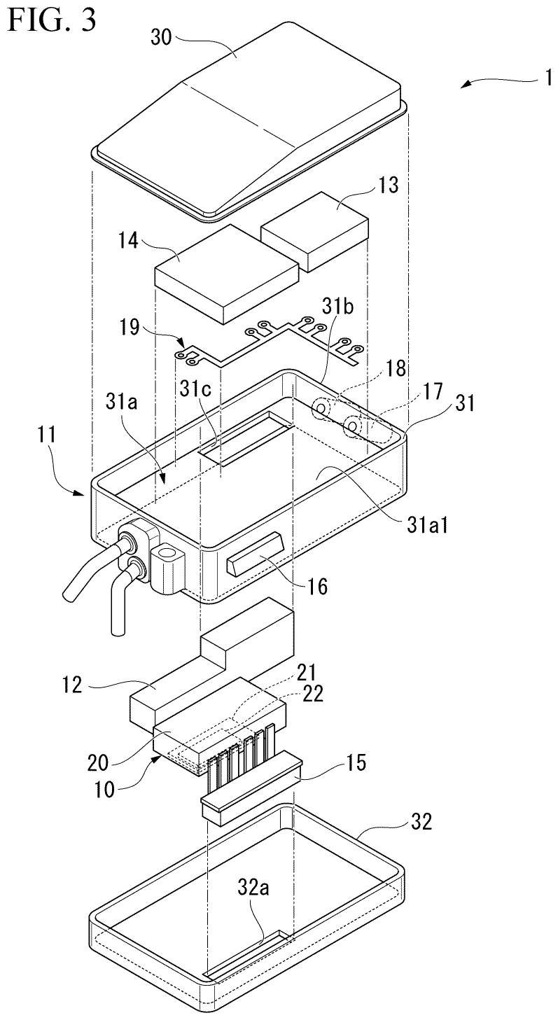

FIG. 3 is an exploded perspective view showing a structural schematic configuration of the power conversion device 1 of the present embodiment. As shown in FIG. 3, the power conversion device 1 of the present embodiment includes an intelligent power module 10, a main body case 11, a capacitor unit 12, a reactor unit 13, a DC/DC converter unit 14, a motor output connector 15, a DC/DC converter output connector 16 (output connector), a DC power supply connector 17 (first connector), an air-conditioning equipment connector 18 (second connector), and an internal bus bar 19 (bus bar).

In the following description, for convenience of description, a side on which the DC/DC converter unit 14 and the like are positioned with respect to a partition wall portion 31a of a central plate 31, which will be described later, of the main body case 11 is referred to as an upper side, and a side on which the intelligent power module 10 is positioned with respect to the partition wall portion 31a of the central plate 31, which will be described later, of the main body case 11 is referred to as a lower side. However, the installation posture of the power conversion device 1 is not particularly limited. A direction orthogonal to the up-down direction is referred to as a “horizontal direction.” A view of the power conversion device 1 as viewed in the up-down direction is referred to as a “plan view.”

The intelligent power module 10 includes a power module 20, a gate driver board 21, an ECU board 22, and the like. The power module 20 includes a plurality of power devices D having semiconductor elements, a power module case made of a resin that accommodates the power devices D, and the like.

The gate driver board 21 is a board provided with gate drivers that generate drive signals for the buck-boost converter 2 or the inverter 3, which are formed of the power devices D. Such a gate driver board 21 is stacked on the power module 20. The ECU board 22 is a board provided with an electronic control unit (ECU) that controls the gate driver board 21. The ECU board 22 is stacked on the gate driver board 21. The gate driver board 21 and the ECU board 22 may be integrated together.

The intelligent power module 10 includes the power devices D that form the buck-boost converter 2 or the inverter 3. That is, the intelligent power module 10 forms at least a part of the buck-boost converter 2 or the inverter 3.

The main body case 11 is a case that accommodates the intelligent power module 10, the capacitor unit 12, the reactor unit 13, the DC/DC converter unit 14, and the like. The main body case 11 includes an upper cover 30, the central plate 31 (support plate), and a lower cover 32. The upper cover 30, the central plate 31, and the lower cover 32 are formed to be separable in the up-down direction.

The upper cover 30 is a portion that covers, from above, the DC/DC converter unit 14 and the reactor unit 13 fixed to the central plate 31 from above. That is, the upper cover 30 is fastened to the central plate 31 through bolts (not shown) or the like.

The central plate 31 is a support plate positioned between the upper cover 30 and the lower cover 32. The central plate 31 includes the flat plate-shaped partition wall portion 31a and a surrounding wall portion 31b provided to surround the partition wall portion 31a from the side of the partition wall portion 31a.

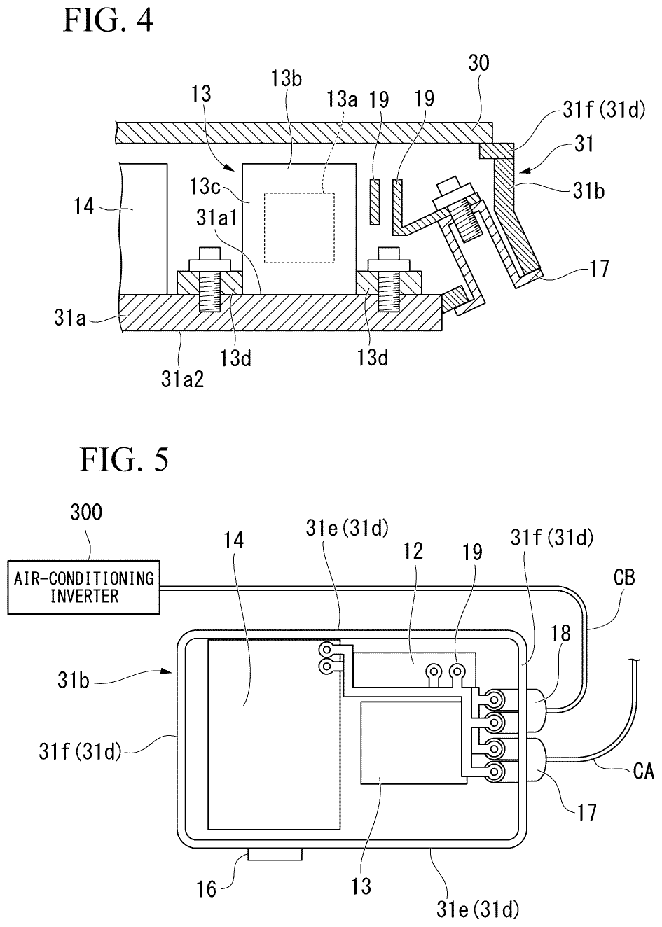

The partition wall portion 31a is disposed such that one surface (hereinafter, referred to as an upper surface 31a1) thereof faces upward and the other surface (hereinafter, referred to as a lower surface 31a2) thereof faces downward. The lower surface 31a2 is shown in FIG. 4. Such a partition wall portion 31a supports, for example, the intelligent power module 10, the capacitor unit 12, the reactor unit 13, and the DC/DC converter unit 14. The partition wall portion 31a may directly support the intelligent power module 10, the capacitor unit 12, the reactor unit 13, and the DC/DC converter unit 14 or may indirectly support the intelligent power module 10, the capacitor unit 12, the reactor unit 13, and the DC/DC converter unit 14 through other portions.

In the present embodiment, the reactor unit 13 and the DC/DC converter unit 14 are disposed above the partition wall portion 31a. In addition, in the present embodiment, the intelligent power module 10 is disposed below the partition wall portion 31a. In addition, in the present embodiment, part of the capacitor unit 12 is provided to penetrate the partition wall portion 31a in the up-down direction. Therefore, the partition wall portion 31a is provided with an insertion opening 31c through which the capacitor unit 12 is inserted.

The intelligent power module 10, the capacitor unit 12, the reactor unit 13, and the DC/DC converter unit 14 are fastened by bolts or the like to bosses or the like provided in the partition wall portion 31a.

Flow paths (not shown) that guide a cooling liquid are provided inside the partition wall portion 31a. By flowing the cooling liquid through the flow paths, the partition wall portion 31a functions as a cooling jacket, and the intelligent power module 10, the capacitor unit 12, the reactor unit 13, and the DC/DC converter unit 14 are cooled.

The surrounding wall portion 31b is provided to surround the intelligent power module 10, the capacitor unit 12, the reactor unit 13, and the DC/DC converter unit 14 from the side of them. The surrounding wall portion 31b is connected to the edge portion of the partition wall portion 31a and is provided to protrude upward and downward from the partition wall portion 31a. The upper end of the surrounding wall portion 31b is in contact with the upper cover 30. In addition, the lower end of the surrounding wall portion 31b is in contact with the lower cover 32.

The lower cover 32 is a portion that covers, from below, the intelligent power module 10 fixed to the central plate 31 from below. In addition, the lower cover 32 also covers the capacitor unit 12 from below. Such a lower cover 32 is fastened to the central plate 31 through bolts (not shown) or the like.

In addition, the lower cover 32 is provided with an opening portion 32a for exposing the motor output connector 15. A motor-side connector (not shown) is mounted on the motor output connector 15 through the opening portion 32a.

The capacitor unit 12 is connected to the intelligent power module 10 and is disposed on a side of the power module 20. The capacitor unit 12 is a unit including the capacitors C provided in the buck-boost converter 2. The capacitor unit 12 includes elements that form the capacitors C and a housing that covers the elements.

In the present embodiment, the capacitor unit 12 includes the first capacitor C1 and the second capacitor C2 provided in the buck-boost converter 2. In the capacitor unit 12, the elements forming the first capacitor C1 are disposed inside the capacitor unit 12 to be positioned above the partition wall portion 31a. In addition, the elements forming the second capacitor C2 are disposed inside the capacitor unit 12 to be positioned below the partition wall portion 31a.

The reactor unit 13 is fixed to the central plate 31. The reactor unit 13 is connected to the intelligent power module 10 through a bus bar (not shown) and is disposed above the central plate 31 in the present embodiment. The reactor unit 13 is a unit including the reactor L provided in the buck-boost converter 2.

FIG. 4 is a schematic cross-sectional view including the reactor unit 13 in the power conversion device 1 of the present embodiment. As shown in FIG. 4, in the present embodiment, the reactor unit 13 includes a reactor case 13b (case) that covers a reactor element 13a. Further, the reactor case 13b includes a case main body 13c accommodating the reactor element 13a, and a flange portion 13d protruding laterally from the lower end of the case main body 13c and fastened to the central plate 31. In this way, in the present embodiment, the reactor unit 13 is fastened to the central plate 31 by fastening the flange portion 13d to the partition wall portion 31a of the central plate 31.

The DC/DC converter unit 14 is fixed to the central plate 31. The DC/DC converter unit 14 is connected to the intelligent power module 10 through a bus bar (not shown) and is disposed above the central plate 31 in the present embodiment. The DC/DC converter unit 14 is a unit forming the DC/DC converter 4 shown in FIG. 1.

The motor output connector 15 is a unit to which the motor-side connector is connected. In the present embodiment, the motor output connector 15 is disposed below the partition wall portion 31a of the central plate 31. In addition, the motor output connector 15 is disposed further below the intelligent power module 10. Such a motor output connector 15 is connected to the power module 20 through a motor connection bus bar.

The DC/DC converter output connector 16 is a connector for outputting electric power output from the DC/DC converter 4 to auxiliary devices and the like outside the power conversion device 1. FIG. 5 is a schematic view in which the upper cover 30 of the main body case 11 is omitted. As shown in FIG. 5, the surrounding wall portion 31b of the central plate 31 is formed in a rectangular shape in a plan view by connecting four side walls 31d. The four side walls 31d include long side walls 31e that form long sides of the rectangular shape and short side walls 31f that form short sides of the rectangular shape. The DC/DC converter output connector 16 is provided on one of the two long side walls 31e of the rectangular surrounding wall portion 31b. A connector connected to, for example, the low voltage battery LB is mounted on the DC/DC converter output connector 16. As a result, the DC/DC converter unit 14 and the low voltage battery LB are electrically connected.

The DC power supply connector 17 is a connector configured to be connected to the high voltage battery HB. As shown in FIG. 5, a cable CA connected to the high voltage battery HB is mounted on the DC power supply connector 17. As a result, the power conversion device 1 and the high voltage battery HB are electrically connected. As shown in FIG. 5, the DC power supply connector 17 is held by one (the short side wall 31f on the reactor unit 13-side) of the short side walls 31f of the surrounding wall portion 31b of the central plate 31.

The DC power supply connector 17 is provided to protrude from an outer wall surface (outer surface) of the short side wall 31f. As shown in FIG. 4, the DC power supply connector 17 is formed such that the cable CA is mountable thereon in a direction inclined relative to a wall surface (the upper surface 31a1 or the lower surface 31a2) of the partition wall portion 31a. The angle between the upper surface 31a1 or the lower surface 31a2 and the inclined direction is greater than −90° and less than 0°, or greater than 0° and less than 90°. In the present embodiment, the DC power supply connector 17 is formed such that the cable CA is mountable thereon from obliquely below.

As shown in FIG. 5, in a plan view, the DC/DC converter unit 14 is positioned farther from the DC power supply connector 17 than the reactor unit 13. That is, in the power conversion device 1 of the present embodiment, the DC/DC converter unit 14 that handles a lower voltage than the reactor unit 13 is disposed farther from the DC power supply connector 17 to which a high voltage is input than the reactor unit 13.

The air-conditioning equipment connector 18 is a connector configured to be connected to air-conditioning equipment (not shown). As shown in FIG. 5, a cable CB connected to the air-conditioning equipment is mounted on the air-conditioning equipment connector 18. As a result, the power conversion device 1 and the air-conditioning equipment are electrically connected. For example, as shown in FIG. 5, the air-conditioning equipment connector 18 is connected to an air-conditioning equipment inverter 300 of the air-conditioning equipment.

As shown in FIG. 5, the air-conditioning equipment connector 18 is held by one (the short side wall 31f on the reactor unit 13-side) of the short side walls 31f of the surrounding wall portion 31b of the central plate 31. That is, the air-conditioning equipment connector 18 is held by the same short side wall 31f as the DC power supply connector 17. The air-conditioning equipment connector 18 is disposed at a position displaced in the horizontal direction from the DC power supply connector 17 and is held by the central plate 31 to be adjacent to the DC power supply connector 17.

The air-conditioning equipment connector 18 is provided to protrude from the outer wall surface (outer surface) of the short side wall 31f. The air-conditioning equipment connector 18 is formed such that the cable CB is mountable thereon in a direction inclined relative to a wall surface (the upper surface 31a1 or the lower surface 31a2) of the partition wall portion 31a. The angle between the upper surface 31a1 or the lower surface 31a2 and the inclined direction is greater than −90° and less than 0°, or greater than 0° and less than 90°. In the present embodiment, the air-conditioning equipment connector 18 is formed such that the cable CB is mountable thereon from obliquely below. In the present embodiment, the DC power supply connector 17 and the air-conditioning equipment connector 18 are formed such that the mounting angles of the cable CA and the cable CB are the same.

In addition, in the present embodiment, the air-conditioning equipment connector 18 is positioned farther from the side wall (the long side wall 31e) on which the DC/DC converter output connector 16 is provided than the DC power supply connector 17 in a plan view. Therefore, the cable CB to be connected to the air-conditioning equipment connector 18 is routed without intersecting the cable CA connected to the DC power supply connector 17 or a cable (not shown) connected to the DC/DC converter output connector 16. Therefore, it becomes easy to route the cable CB to be connected to the air-conditioning equipment connector 18.

As shown in FIG. 5, the internal bus bar 19 is disposed inside the main body case 11 (above the upper surface 31a1 of the partition wall portion 31a) and is a strip-shaped conductor portion that connects the DC power supply connector 17 and the air-conditioning equipment connector 18 to the capacitor unit 12 and the DC/DC converter unit 14. That is, the air-conditioning equipment connector 18, the capacitor unit 12, and the DC/DC converter unit 14 are connected to the high voltage battery HB through the DC power supply connector 17.

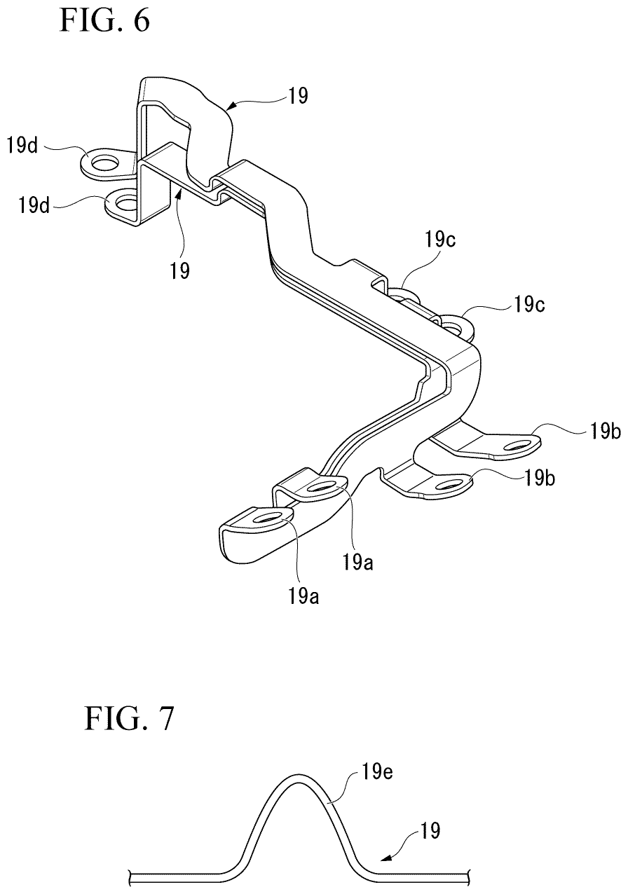

FIG. 6 is a perspective view of the internal bus bar 19. As shown in FIG. 6, the power conversion device 1 of the present embodiment includes two internal bus bars 19. As shown in FIG. 5, each internal bus bar 19 is connected to the DC/DC converter unit 14 without crossing the DC/DC converter unit 14. One internal bus bar 19 is connected to a positive terminal of the high voltage battery HB. In addition, the other internal bus bar 19 is connected to a negative terminal of the high voltage battery HB. An insulating cover may be mounted on these two internal bus bars 19 as needed.

Each internal bus bar 19 includes a first connection portion 19a connected to the DC power supply connector 17, a second connection portion 19b connected to the air-conditioning equipment connector 18, a third connection portion 19c connected to the capacitor unit 12, and a fourth connection portion 19d connected to the DC/DC converter unit 14.

As shown in FIG. 4, the first connection portion 19a (refer to FIG. 6) is disposed at the back portion of the DC power supply connector 17 and comes into contact with the terminal of the cable CA mounted on the DC power supply connector 17. In addition, the second connection portion 19b (refer to FIG. 6) is disposed in the back portion of the air-conditioning equipment connector 18 and comes into contact with the terminal of the cable CB mounted on the air-conditioning equipment connector 18. As shown in FIG. 4, an intermediate portion of the internal bus bar 19 is disposed above the flange portion 13d of the reactor unit 13.

In addition, each internal bus bar 19 may include a stress relaxation portion 19e at an intermediate portion thereof as shown in FIG. 7. The stress relaxation portion 19e is formed by curving the intermediate portion of the internal bus bar 19. Such a stress relaxation portion 19e is an elastically deformable portion and can absorb, by elastically deforming, stress generated when the first connection portion 19a or the second connection portion 19b is connected to a counterpart member.

In addition, a portion of the internal bus bar 19 in the present embodiment between the first connection portion 19a connected to the DC power supply connector 17 and the second connection portion 19b connected to the air-conditioning equipment connector 18 is fixed to the central plate 31. Specifically, the portion between the first connection portion 19a and the second connection portion 19b is fastened to a boss (not shown) or the like provided in the central plate 31.

The power conversion device 1 of the present embodiment may include a bus bar through which electric power flows, in addition to the internal bus bar 19. For example, the power conversion device 1 may include a bus bar that connects the capacitor unit 12 and the reactor unit 13. Further, the internal bus bar 19 may include a portion that connects the capacitor unit 12 and the reactor unit 13.

In the power conversion device 1 of the present embodiment, the DC power supply connector 17 is connected to the high voltage battery HB through the cable CA, and DC power is supplied thereto from the high voltage battery HB. The power conversion device 1 steps up the DC power with the buck-boost converter 2, converts the stepped up DC power into alternating current with the inverter 3, and supplies the alternating current to the motor M. In addition, the power conversion device 1 converts regenerative power supplied from each motor M into DC power with the inverter 3, steps down the DC power with the buck-boost converter 2, and supplies the stepped down DC power to the high voltage battery HB.

Further, the power conversion device 1 of the present embodiment supplies DC power supplied from the high voltage battery HB to the air-conditioning equipment through the internal bus bar 19 and the air-conditioning equipment connector 18. In addition, the power conversion device 1 of the present embodiment steps down DC power supplied from the high voltage battery HB with the DC/DC converter 4 and supplies the stepped down DC power to the low voltage battery LB.

The power conversion device 1 of the present embodiment described above includes the capacitor unit 12, the reactor unit 13, the DC/DC converter unit 14, and the power module 20. The capacitor unit 12, the reactor unit 13, the DC/DC converter unit 14, and the power module 20 form the power conversion circuit H. In addition, the power conversion device 1 of the present embodiment includes the central plate 31, the DC power supply connector 17, the air-conditioning equipment connector 18, and the internal bus bar 19. The central plate 31 includes the flat plate-shaped partition wall portion 31a that supports the capacitor unit 12, the reactor unit 13, the DC/DC converter unit 14, and the power module 20. The DC power supply connector 17 is held by the central plate 31. The air-conditioning equipment connector 18 is held by the central plate 31 to be adjacent to the DC power supply connector 17. The internal bus bar 19 connects the DC power supply connector 17 and the air-conditioning equipment connector 18 to at least the capacitor unit 12 and the DC/DC converter unit 14. In addition, the central plate 31 includes the surrounding wall portion 31b that surrounds the partition wall portion 31a from the side of the partition wall portion 31a. The DC power supply connector 17 and the air-conditioning equipment connector 18 are provided to protrude from the outer wall surface of the surrounding wall portion 31b and are formed such that the cables are mountable thereon in a direction inclined relative to the wall surface of the partition wall portion 31a.

In the power conversion device 1 of the present embodiment, the DC power supply connector 17 and the air-conditioning equipment connector 18 adjacent to each other are provided to protrude from the outer wall surface of the surrounding wall portion 31b of the central plate 31 and are formed such that the cables are mountable thereon in a direction inclined relative to the flat plate-shaped partition wall portion 31a. Therefore, it is possible to further reduce the amount of protrusion of the DC power supply connector 17 and the air-conditioning equipment connector 18 from the outer wall surface than a case where the cables are mounted on the DC power supply connector 17 and the air-conditioning equipment connector 18 in the horizontal direction with respect to the flat plate-shaped partition wall portion 31a. In addition, it is possible to further reduce the amount of protrusion of the cables in the horizontal direction than a case where the cables are mounted on the DC power supply connector 17 and the air-conditioning equipment connector 18 in the horizontal direction. Therefore, the power conversion device of the present embodiment can reduce the installation space therefor when viewed in the normal direction (the up-down direction) of the partition wall portion 31a.

In addition, in the power conversion device 1 of the present embodiment, the reactor unit 13, the DC/DC converter unit 14, and the internal bus bar 19 are disposed above the upper surface that is one of wall surfaces of the partition wall portion 31a. Further, the internal bus bar 19 is connected to the DC/DC converter unit 14 without crossing the DC/DC converter unit 14 in a plan view.

In a case where the internal bus bar 19 crosses the DC/DC converter unit 14, it is necessary to install a shield plate or the like between the internal bus bar 19 and the DC/DC converter unit 14 in order to reduce noise caused by a current flowing through the internal bus bar 19. On the other hand, in the power conversion device 1 of the present embodiment, since the internal bus bar 19 does not cross the DC/DC converter unit 14, it is not necessary to install the shield plate, and it is possible to reduce the weight and the cost.

In addition, in the power conversion device 1 of the present embodiment, the reactor unit 13 includes the reactor case 13b that covers the reactor element 13a. In addition, the reactor case 13b includes the flange portion 13d protruding laterally from the lower end of the case main body 13c and fastened to the central plate 31. In addition, the DC power supply connector 17 and the air-conditioning equipment connector 18 are formed such that the cables are mountable thereon from obliquely below. Further, the intermediate portion of the internal bus bar 19 is positioned above the flange portion 13d.

In the power conversion device 1 of the present embodiment, the DC power supply connector 17 and the air-conditioning equipment connector 18 are formed such that the cables are mountable thereon from obliquely below. Therefore, the back end portions of the DC power supply connector 17 and the air-conditioning equipment connector 18 are positioned above the inlet openings of the DC power supply connector 17 and the air-conditioning equipment connector 18. Thus, in the power conversion device 1 of the present embodiment, the internal bus bar 19 can be disposed higher than a case where the cables are mounted on the DC power supply connector 17 and the air-conditioning equipment connector 18 in the horizontal direction, and part of the internal bus bar 19 can be positioned above the flange portion 13d of the reactor unit 13. In this way, by positioning the intermediate portion of the internal bus bar 19 above the flange portion 13d, it is possible to reduce the size of the power conversion device 1 in a plan view.

In addition, in the power conversion device 1 of the present embodiment, the internal bus bar 19 includes the first connection portion 19a connected to the DC power supply connector 17 and the second connection portion 19b connected to the air-conditioning equipment connector 18. In addition, a portion of the internal bus bar 19 between the first connection portion 19a and the second connection portion 19b is fixed to the central plate 31.

For example, by fixing a portion close to the first connection portion 19a to the central plate 31, it is possible to prevent the first connection portion 19a and the terminal of the cable CA mounted on the DC power supply connector 17 from being separated from each other due to vibration or the like of the vehicle 100. In addition, similarly, by fixing a portion close to the second connection portion 19b to the central plate 31, it is possible to prevent the second connection portion 19b and the terminal of the cable CB mounted on the air-conditioning equipment connector 18 from being separated from each other due to vibration or the like of the vehicle 100. In the present embodiment, since the portion between the first connection portion 19a and the second connection portion 19b is fixed to the central plate 31, it is possible to prevent both the first connection portion 19a and the second connection portion 19b from being separated from the terminals of the cables with one fixing point.

In addition, in the power conversion device 1 of the present embodiment, the internal bus bar 19 includes the stress relaxation portion 19e formed by curving the intermediate portion thereof. According to the power conversion device 1 of the present embodiment, the internal bus bar 19 can absorb, by elastically deforming, stress generated by the first connection portion 19a or the second connection portion 19b being brought into contact with the terminal of the cable from obliquely below.

In addition, in the power conversion device 1 of the present embodiment, the DC/DC converter unit 14 is positioned farther from the DC power supply connector 17 than the reactor unit 13 in a plan view. According to the power conversion device 1 of the present embodiment, the DC/DC converter unit 14 that handles a lower voltage than the reactor unit 13 is disposed farther from the DC power supply connector 17 to which a high voltage is input than the reactor unit 13. Accordingly, it is possible to shorten the internal bus bar 19.

In addition, in the power conversion device 1 of the present embodiment, the surrounding wall portion 31b is formed in a rectangular shape in a plan view. In addition, the DC power supply connector 17 and the air-conditioning equipment connector 18 are provided on the side wall 31d of the surrounding wall portion 31b corresponding to one side of the rectangular shape. In addition, the DC/DC converter output connector 16 of the DC/DC converter unit 14 is provided on the long side wall 31e connected to the short side wall 31f provided with the DC power supply connector 17 and the air-conditioning equipment connector 18. In addition, the air-conditioning equipment connector 18 is an air-conditioning equipment connector configured to be connected to the air-conditioning equipment inverter 300 and is positioned farther from the long side wall 31e provided with the DC/DC converter output connector 16 than the DC power supply connector 17 in a plan view.

According to the power conversion device 1 of the present embodiment, the cable CB to be connected to the air-conditioning equipment connector 18 can be routed so as not to intersect with the cable CA connected to the DC power supply connector 17 or a cable (not shown) connected to the DC/DC converter output connector 16 in a plan view. Therefore, it becomes easy to route the cable CB to be connected to the air-conditioning equipment connector 18.

Although the appropriate embodiments of the present invention have been described above with reference to the accompanying drawings, the present invention is not limited to the above embodiments. The shapes, combinations and the like of the constituent members shown in the above-described embodiment are merely examples and can be variously changed based on design requirements and the like within the scope of the present invention.

For example, in the above-described embodiment, the configuration in which the cables can be mounted on the DC power supply connector 17 and the air-conditioning equipment connector 18 from obliquely below has been described. However, the present invention is not limited to this, and a configuration can also be adopted in which the cables can be mounted on the DC power supply connector 17 and the air-conditioning equipment connector 18 from obliquely above.

In addition, in the above-described embodiment, the configuration in which the first connector is the DC power supply connector 17 and the second connector is the air-conditioning equipment connector 18 has been described. However, the present invention is not limited to this. The first connector and the second connector adjacent to each other may be other types of connectors.

The above-described embodiments can also be described as, for example, the following appendices.

### APPENDIX 1

A power conversion device includes: a capacitor unit, a reactor unit, a DC/DC converter unit, and a power module forming a power conversion circuit; a support plate including a flat plate-shaped partition wall portion supporting the capacitor unit, the reactor unit, the DC/DC converter unit, and the power module; a first connector held by the support plate; a second connector held by the support plate to be adjacent to the first connector; and a bus bar connecting the first connector and the second connector to at least the capacitor unit and the DC/DC converter unit, in which the support plate includes a surrounding wall portion surrounding the partition wall portion from a side thereof, and the first connector and the second connector are provided to protrude from an outer wall surface of the surrounding wall portion and are formed such that cables are mountable thereon in a direction inclined relative to a wall surface of the partition wall portion.

### APPENDIX 2

The power conversion device according to Appendix 1 is in which the reactor unit, the DC/DC converter unit, and the bus bar are disposed above an upper surface that is one of wall surfaces of the partition wall portion, and the bus bar is connected to the DC/DC converter unit without crossing the DC/DC converter unit in a plan view.

### APPENDIX 3

The power conversion device according to Appendix 1 or 2 is in which the reactor unit includes a case covering a reactor element, the case includes a flange portion protruding laterally from a lower end of a case main body and fastened to the support plate, the first connector and the second connector are formed such that the cables are mountable thereon from obliquely below, and an intermediate portion of the bus bar is positioned above the flange portion.

### APPENDIX 4

The power conversion device according to any one of Appendixes 1 to 3 is in which the bus bar includes a first connection portion connected to the first connector and a second connection portion connected to the second connector, and a portion of the bus bar between the first connection portion and the second connection portion is fixed to the support plate.

### APPENDIX 5

The power conversion device according to any one of Appendixes 1 to 4 is in which the bus bar includes a stress relaxation portion formed by curving an intermediate portion thereof.

### APPENDIX 6

The power conversion device according to any one of Appendixes 1 to 5 is in which the first connector is a DC power supply connector configured to be connected to a battery, and the DC/DC converter unit is positioned farther from the DC power supply connector than the reactor unit in a plan view.

### APPENDIX 7

The power conversion device according to Appendix 6 is in which the surrounding wall portion is formed in a rectangular shape in the plan view, the first connector and the second connector are provided on a side wall of the surrounding wall portion corresponding to one side of the rectangular shape, an output connector of the DC/DC converter unit is provided on another side wall of the surrounding wall portion connected to the side wall on which the first connector and the second connector are provided, and the second connector is an air-conditioning equipment connector configured to be connected to an air-conditioning equipment inverter and is positioned farther from the side wall on which the output connector is provided than the first connector in the plan view.

What is claimed is:

1. A power conversion device comprising:
a capacitor unit, a reactor unit, a DC/DC converter unit, and a power module forming a power conversion circuit;
a support plate including a flat plate-shaped partition wall portion supporting the capacitor unit, the reactor unit, the DC/DC converter unit, and the power module;
a first connector held by the support plate;
a second connector held by the support plate to be adjacent to the first connector; and
a bus bar connecting the first connector and the second connector to at least the capacitor unit and the DC/DC converter unit,
in which the support plate includes a surrounding wall portion surrounding the partition wall portion from a side thereof, and
the first connector and the second connector are provided to protrude from an outer wall surface of the surrounding wall portion and are formed such that cables are mountable thereon in a direction inclined relative to a wall surface of the partition wall portion.

2. The power conversion device according to claim 1,
in which the reactor unit, the DC/DC converter unit, and the bus bar are disposed above an upper surface that is one of wall surfaces of the partition wall portion, and
the bus bar is connected to the DC/DC converter unit without crossing the DC/DC converter unit in a plan view.

3. The power conversion device according to claim 1,
in which the reactor unit includes a case covering a reactor element,
the case includes a flange portion protruding laterally from a lower end of a case main body and fastened to the support plate,
the first connector and the second connector are formed such that the cables are mountable thereon from obliquely below, and
an intermediate portion of the bus bar is positioned above the flange portion.

4. The power conversion device according to claim 1,
in which the bus bar includes a first connection portion connected to the first connector and a second connection portion connected to the second connector, and a portion of the bus bar between the first connection portion and the second connection portion is fixed to the support plate.

5. The power conversion device according to claim 1,
in which the bus bar includes a stress relaxation portion formed by curving an intermediate portion thereof.

6. The power conversion device according to claim 1,
in which the first connector is a DC power supply connector configured to be connected to a battery, and
the DC/DC converter unit is positioned farther from the DC power supply connector than the reactor unit in a plan view.

7. The power conversion device according to claim 6,
in which the surrounding wall portion is formed in a rectangular shape in the plan view,
the first connector and the second connector are provided on a side wall of the surrounding wall portion corresponding to one side of the rectangular shape,
an output connector of the DC/DC converter unit is provided on another side wall of the surrounding wall portion connected to the side wall on which the first connector and the second connector are provided, and
the second connector is an air-conditioning equipment connector configured to be connected to an air-conditioning equipment inverter and is positioned farther from the side wall on which the output connector is provided than the first connector in the plan view.
